(19) United States
(12) Patent Application Publication
(10) Pub. No.: US 2021/0257579 A1
(43) Pub. Date: Aug. 19, 2021

(54) DISPLAY DEVICE

(71) Applicant: SHARP KABUSHIKI KAISHA, Sakai City, Osaka (JP)

(72) Inventors: TOHRU OKABE, Sakai City, Osaka (JP); TAKESHI YANEDA, Osaka City, Osaka (JP)

(21) Appl. No.: 17/269,720

(22) PCT Filed: Aug. 23, 2018
(86) PCT No.: PCT/JP2018/031177

§ 371 Date: Feb. 19, 2021

(51) Int. Cl. H01L 51/52; H01L 27/32

(52) U.S. Cl. CPC H01L 51/525; H01L 27/3276

(57) ABSTRACT

A display area is provided with a plurality of first conductive layers formed of the same material and in the same layer as first electrodes. The first conductive layers are each positioned under a corresponding one of plurality of first photo spacers. A frame area is provided with a second conductive layer formed of the same material and in the same layer as the first electrodes. The second conductive layer includes a plurality of openings each formed under a corresponding one of a plurality of second photo spacers.

### TECHNICAL FIELD

The present invention relates to a display device.

### BACKGROUND ART

In recent years, light-emitting organic electroluminescence (EL) display devices using organic EL elements are drawing attention as a replacement for liquid crystal display devices. An organic EL element includes, for example, a plurality of first electrodes arranged on a planarization film in a matrix, a grid-like edge cover provided to cover edges of the first electrodes, a plurality of organic EL layers arranged on the first electrodes in a matrix, and a second electrode provided to cover the edge cover and the organic EL layers. In forming the organic EL layers and the second electrode, a mask for vapor deposition is placed on a photo spacer formed on a substrate, and materials for the organic EL layers and the second electrode are vapor-deposited on the substrate through an opening of the mask.

Patent Document 1 discloses, for example, a display device including: a bank (an edge cover) surrounding first electrodes and defining a light-emitting area; and a support (a photo spacer) provided on the bank and supporting a mask for vapor deposition.

### CITATION LIST

### Patent Literature

[Patent Document] Japanese Unexamined Patent Application Publication No. 2014-041740

### SUMMARY OF INVENTION

### Technical Problem

In vapor-depositing such functional layers as the organic EL lavers and the second electrode, a mask for vapor deposition is placed in contact with a top of the photo spacer formed on the substrate. The mask in contact could break the top of the photo spacer. The broken piece of the top of the photo spacer acts as a foreign object, inevitably reducing a throughput yield of organic EL display devices.

In view of the above problem, the present invention is intended to reduce damage to a photo spacer when a mask for vapor deposition comes in contact with the photo spacer.

### Solution to Problem

In order to achieve the above object, a display device according to the present invention includes: a base substrate on which a display area for displaying an image and a frame area around the display area are defined; a TFT layer provided on the base substrate and including a planarization film as a top sursurface of the TFT layer; a light-emitting clement provided on the planarization film in the display area, the light-emitting element including a plurality of first electrodes, a light-emitting layer, and a second electrode stacked in this order; a plurality of first photo spacers provided above the planarization film in the display area; and a plurality of second photo spacers provided on the planarization film in the frame area. The display area is provided with a plurality of first conductive layers formed of the same material and in the same layer as the first electrodes. The first conductive layers are each shaped into an island and positioned under a corresponding one of the first photo spacers. The frame area is provided with a second conductive layer formed of the same material and in the same layer as the first electrodes. The second conductive layer includes a plurality of openings each formed under a corresponding one of the second photo spacers.

### Advantageous Effects of Invention

In the present invention, a display area is provided with a plurality of first conductive layers formed of the same material and in the same layer as plurality of first electrodes. The first conductive layers are each positioned under a corresponding one of a plurality of first photo spacers. A frame area is provided with a second conductive layer formed of the same material and in the same layer as the first electrodes. The second conductive layer includes a plurality of openings each formed under a corresponding one of a plurality of second photo spacers. Such features make it possible to reduce damage to the photo spacers when a mask for vapor deposition comes in contact with the photo spacers.

### BRIEF DESCRIPTION OF DRAWINGS

FIG. 1 is a plan view illustrating a schematic configuration of an organic EL display device according to a first embodiment of the present invention.

FIG. 2 is a plan view illustrating display area of the organic EL display device according to the first embodiment of the present invention.

FIG. 3 is a cross-section of the organic EL display device, taken from line III-III in FIG. 1.

FIG. 4 is an equivalent circuit diagram illustrating a thin-film transistor (TFT) layer included in the organic EL display device according to the first embodiment of the present invention.

FIG. 5 is a cross-section illustrating an organic EL layer included in the organic EL display device according to the first embodiment of the present invention.

FIG. 6 is a cross-section of a frame area included in the organic EL display device, taken from line VI-VI in FIG. 1.

FIG. 7 is a cross-section of the frame area included in the organic EL display device, taken from line VII-VII in FIG. 1.

FIG. 8 is a plan view illustrating how first photo spacers are arranged in the display area of the organic EL display device according to the first embodiment of the present invention.

FIG. 9 is a plan view illustrating how second photo spacers are arranged on a side, of the frame area, not facing a terminal of the organic EL display device according to the first embodiment of the present invention.

FIG. 10 is a plan view illustrating how the second photo spacers are arranged on one of two sides, of the frame area, facing a terminal of the organic EL display device according to the first embodiment of the present invention. The one side is positioned closer to the terminal.

FIG. 11 is a plan view illustrating frame wires arranged in the frame area of the organic EL display device according to the first embodiment of the present invention.

FIG. 12 is a plan view illustrating an area in which the second photo spacers are arranged on the frame area of the organic EL display device according to the first embodiment of the present invention.

FIG. 13 is a plan view illustrating a second conductive layer and a third conductive layer arranged in the frame area of the organic EL display device according to the first embodiment of the present invention.

FIG. 14 is a plan view illustrating how the second photo spacers and third photo spacers are arranged on a side, of the frame area, not facing a terminal of an organic EL display device according to a second embodiment of the present invention.

FIG. 15 is a cross-section corresponding to FIG. 6, and illustrating a frame area of the organic EL display device according to the second embodiment of the present invention.

### DESCRIPTION OF EMBODIMENTS

Described below in derail are embodiments of the present invention, with reference to the drawings. Note that the present invention shall not be limited to the embodiments below.

### First Embodiment

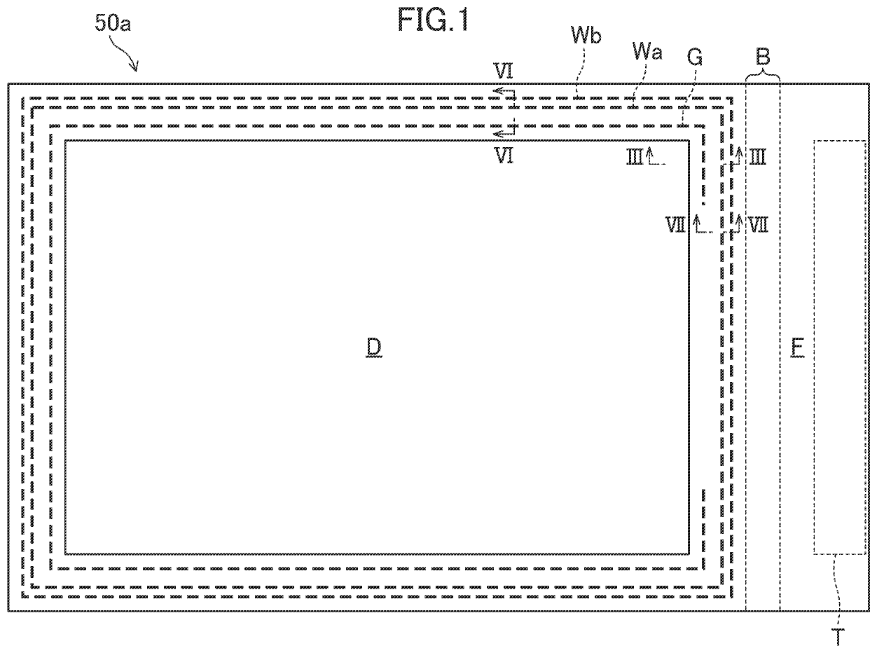

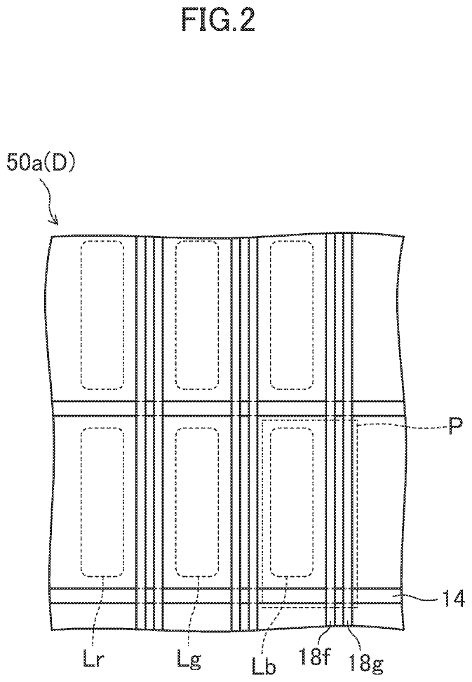

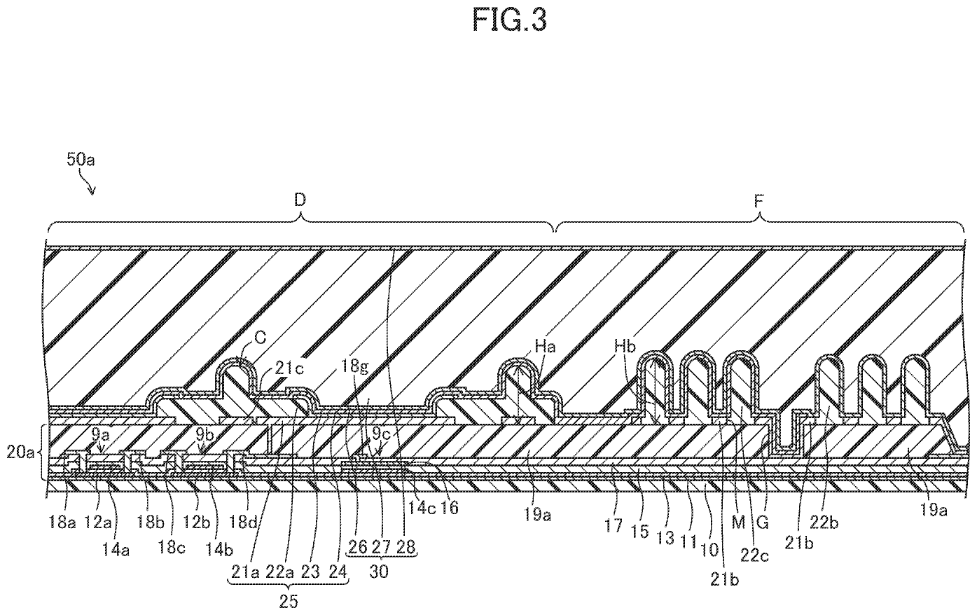

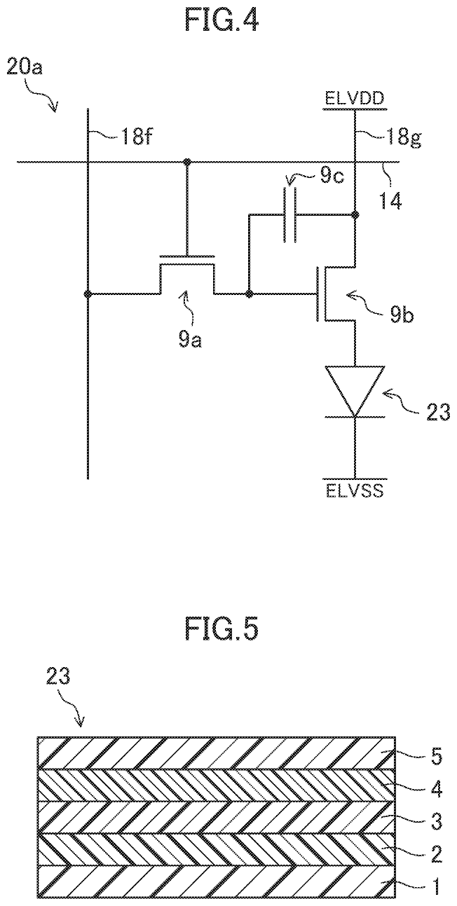

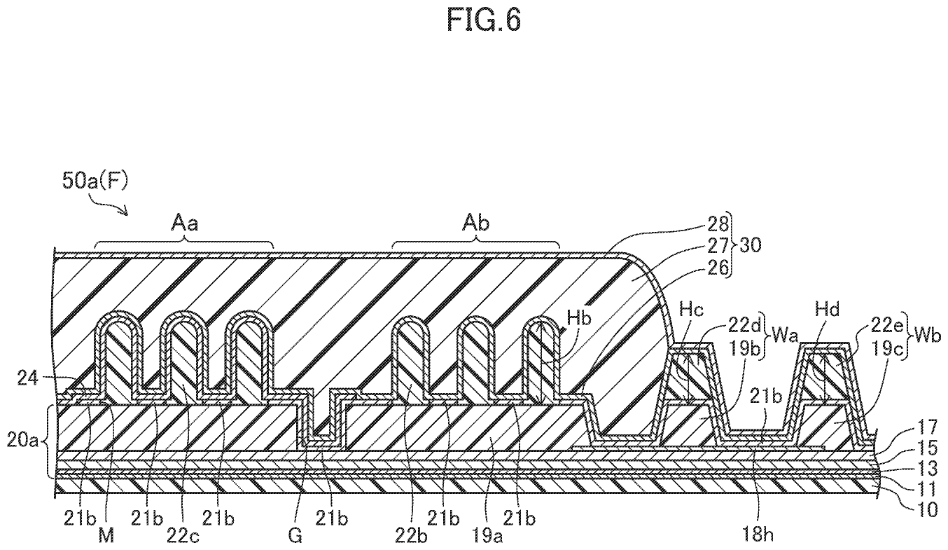

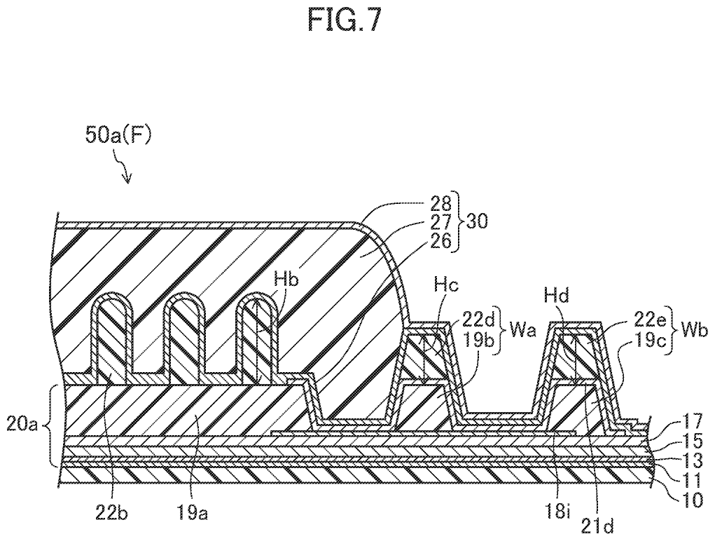

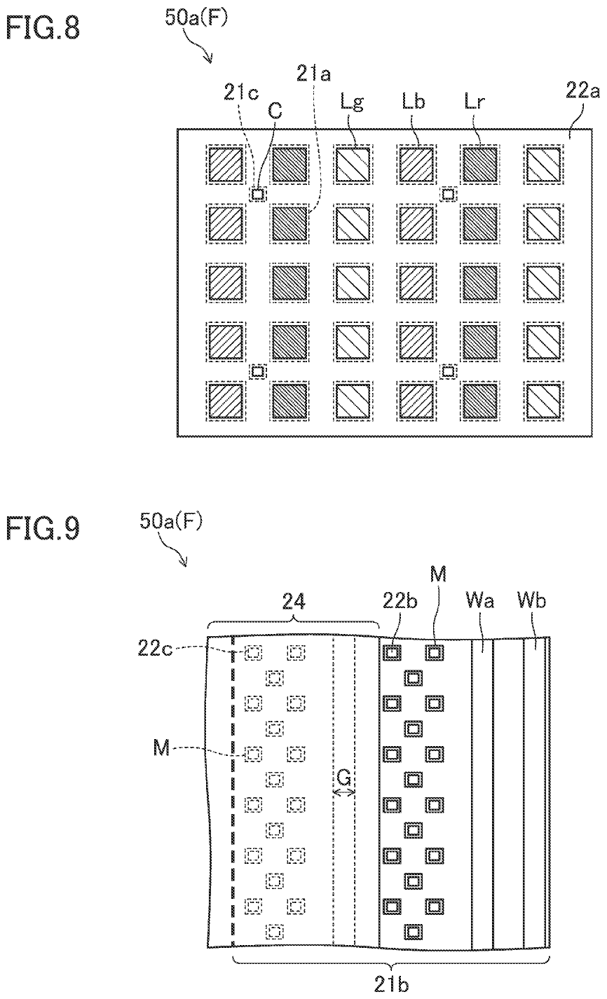

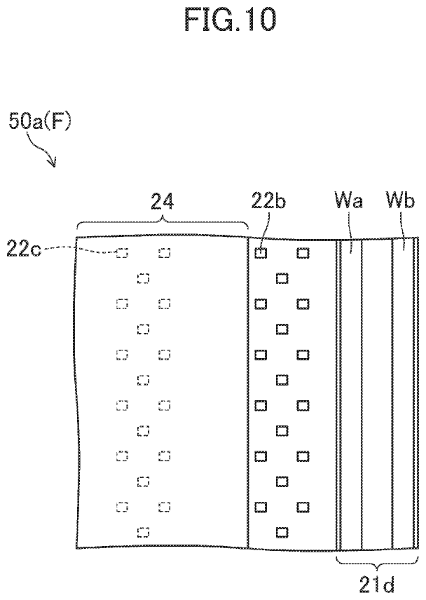

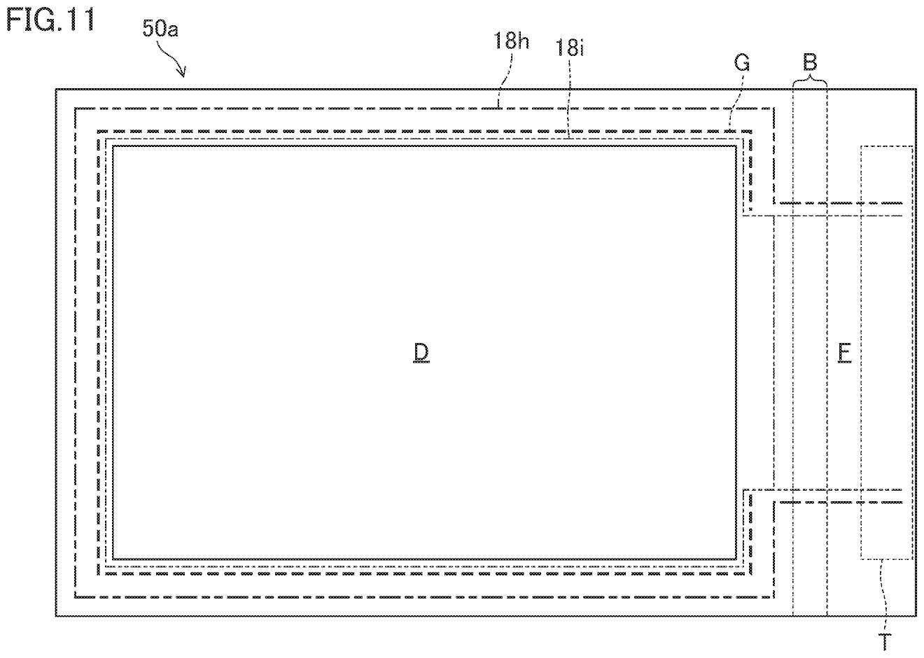

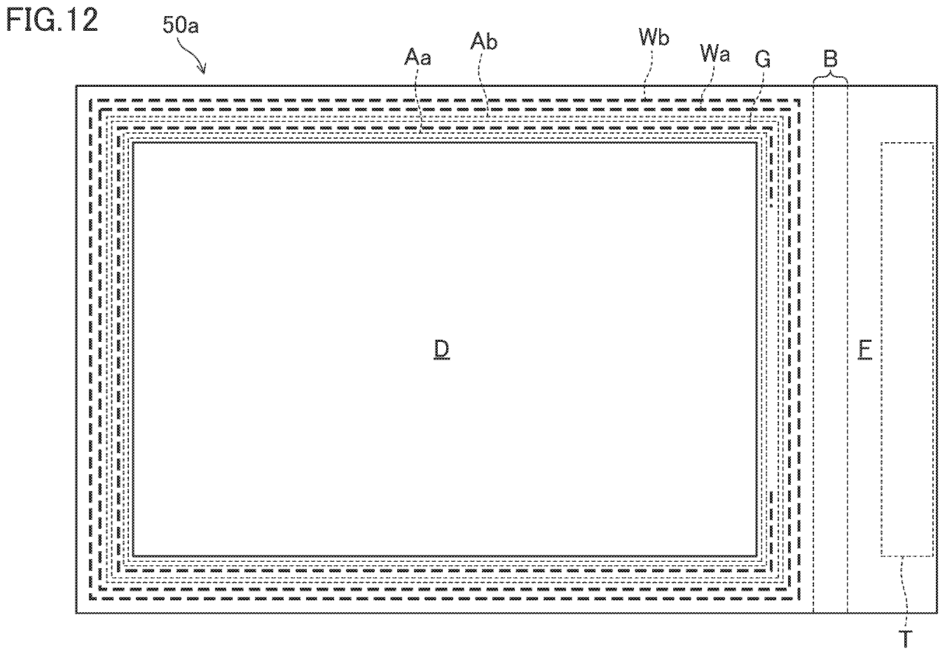

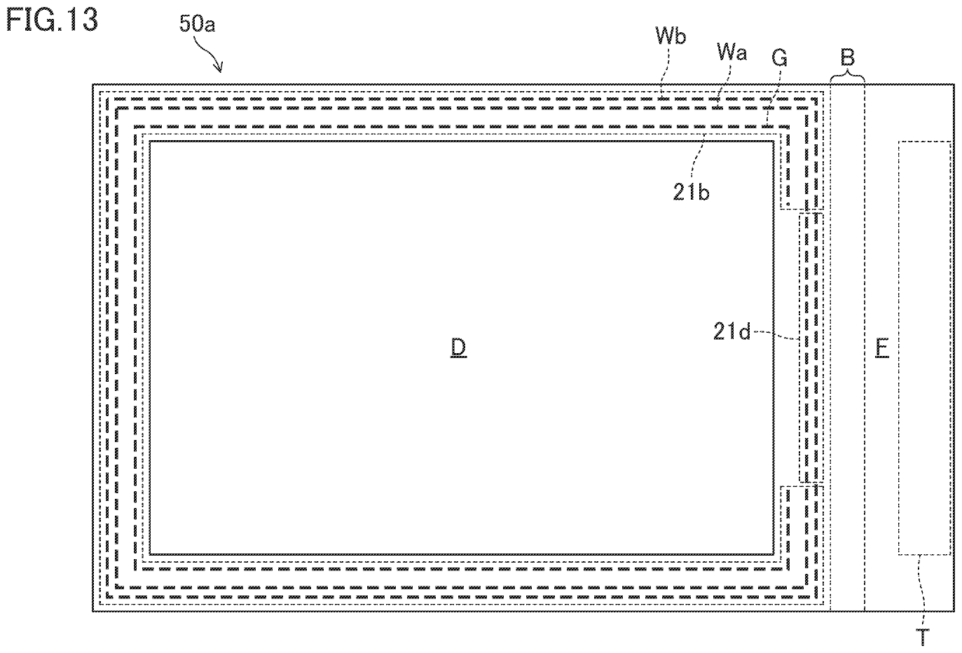

FIGS. 1 to 10 illustrate a first embodiment of a display device according to the present invention. The embodiments below exemplify an organic EL display device including an organic EL element as a display device including a light-emitting element. FIG. 1 is a plan view illustrating a schematic configuration of an organic EL display device 50a according to this embodiment. FIG. 2 is a plan view illustrating a display area L of the organic EL display device 50a, FIG. 3 is a cross-section of the organic EL display device, taken from line III-III in FIG. 1, FIG. 4 is an equivalent circuit diagram illustrating a TFT layer 20a included in the organic EL display device 50a, FIG. 5 is a cross-section illustrating an organic EL layer 23 included in the organic EL display device 50a, FIGS. 6 and 7 are cross-sections of a frame area F included in the organic EL display device 50a, taken from lines VI-VI and VII-VII in FIG. 1. FIG. 8 is a plan view illustrating how a plurality of first photo spacers C are arranged in the display area D of the organic EL display device 50a. FIG. 9 is a plan view illustrating how a plurality of second photo spacers 22b and 22c are arranged on a side, of the frame area F, not facing a terminal T of the organic EL display device 50a. FIG. 10 is a plan view illustrating how the second photo spacers 22b and 22c are arranged on one of two sides, of the frame area F, facing the terminal T of the organic EL display device 50a. The one side is positioned closer to the terminal T. FIG. 11 is a plan view illustrating frame wires 18h and 18i arranged in the frame area F of the organic EL display device 50a. FIG. 12 is a plan view illustrating areas Ab and Aa in which the second photo spacers 22b and 22c are arranged on the frame area of the organic EL display device 50a. FIG. 13 is a plan view illustrating a second conductive layer 21b and a third conductive layer 21d arranged in the frame area F of the organic EL display device 50a.

As illustrated in FIG. 1, the organic EL display device 50a includes, for example: the display area D shaped into a rectangle and displaying an image; and the frame area F provided around the display area D. Note that, in this embodiment, the display area D is, tor example, rectangular. Examples of the rectangle include such substantial rectangles as a rectangle having arc-like sides, a rectangle having rounded corners, and a rectangle having partially notched sides.

As illustrated in FIG. 2, the display area D includes a plurality of sub pixels P arranged in a matrix. In the display area D, as illustrated in FIG. 2, for example, the sub pixels P having red light-emitting areas Lr for presenting red, the sub pixels P having green light-emitting areas Lg for presenting green, and the sub pixels P having blue light-emitting areas Lb for presenting blue are provided next to each other. Note that, in the display area D, for example, neighboring three of the sub pixels P each having one of a red light-emitting area Lr, a green light-emitting area Lg, and a blue light-emitting area Lb constitute one pixel.

In FIG. 1, the frame area F has a right end provided with the terminal T, As illustrated in FIG. 1, the frame area F includes a folding portion B between the display area 1) and the terminal T. The folding portion B, extending in a single direction (a vertical direction in the drawing), is foldable around a folding axis in a vertical direction at an angle of, for example, 180° (foldable in a U-shape). Moreover, in the frame area F, a planarization film 19a to be described later is provided with a trench G shaped into a substantial C-shape and penetrating the planarization film 19a as illustrated in FIGS. 1, 3, and 6. Here, as illustrated in FIG. 1, the trench G is laid into a substantial C-shape to open toward the terminal T in planar view.

As illustrated in FIGS. 3, 6, and 7, the organic EL display device 50a includes: a resin substrate layer 10 provided as a base substrate; the ITT layer 20a provided on the resin substrate layer 10; an organic EL element 25 included in the display area. D and provided on the TFT layer 20a as a light-emitting element; and a sealing film 30 provided to cover the organic EL element 25.

The resin substrate layer 10 is made of, for example, polyimide resin.

As illustrated in FIG. 3, the TFT layer 20a includes: a base coat film 11 provided on the resin substrate layer 10; a plurality of first TFTs 9a, a plurality of second TFT 9b, and a plurality of capacitors 9c provided on the base coat film 11; and the planarization film 19a provided on the first TFTs, the second TFTs, and the capacitors 9c. That is, the TFT layer 20a includes the planarization film 19a as a top surface of the TFT layer 20a. As illustrated in FIGS. 2 and 4, the TFT layer 20a includes a plurality of gate lines 14 horizontally extending in parallel with one another in the drawings. Moreover, as illustrated in FIGS. 2 and 4, the TFT layer 20a includes a plurality of source lines 18f vertically extending in parallel with one another in the drawings. Furthermore, as illustrated in FIGS. 2 and 4, the TFT layer 20a includes a plurality of power source lines 18g vertically extending in parallel with one another in the drawings. Note that, as illustrated in FIG. 2, the power source lines 18g and the source lines 18f are provided next to each other. In the TFT layer 20a, as illustrated in FIG. 4, each of the sub pixels P includes a first TFT 9a, a second TFT 9b, and a capacitor 9c.

The base coat film 11 is, for example, a monolayer inorganic insulating film made of such materials as silicon nitride, silicon oxide, and silicon oxide nitride, or a multilayer inorganic insulating film made of these materials.

As illustrated in FIG. 4, in each sub pixel P, the first TFT 9a is connected to the corresponding gate line 14 and source line 18f. The first TFT 9a illustrated in FIG. 3 includes: a semiconductor layer 12a; a gate insulating film 13; a gate electrode 14a; a first interlayer insulating film 15; a second interlayer insulating film 17; and a source electrode 18a and a drain electrode 18b all of which are provided on the base coat film 11 in this order. The semiconductor layer 12a illustrated in FIG. 3 is, for example, made of polysilicon film and shaped into an island. The semiconductor layer 12a includes a channel region, a source region, and a drain region. The gate insulating film 13 illustrated in FIG. 3 is provided to cover the semiconductor layer 12a. The gate electrode 14a illustrated in FIG. 3 is provided on the gate insulating film 13 to overlap the channel region of the semiconductor layer 12a. The first interlayer insulating film 15 and the second interlayer insulating film 17 illustrated in FIG. 3 are provided in this order to cover the gate electrode 14a. The source electrode 18a and the drain electrode 18b illustrated in FIG. 3 are spaced apart from each other on the second interlayer insulating film 17. As illustrated in FIG. 3, the source electrode 18a and the drain electrode 18b are respectively connected to the source region and the drain region of the semiconductor layer 12a through contact holes each formed in a multilayer film including the gate insulating film 13, the first interlayer insulating film 15, and the second interlayer insulating film 17. Note that the gate insulating film 13, the first interlayer insulating film 15, and the second interlayer insulating film 17 are, for example, a monolayer inorganic insulating film made of such materials as silicon nitride, silicon oxide, and silicon oxide nitride, or a multilayer inorganic insulating film made of these materials.

As illustrated in FIG. 4, in each sub pixel P, the second TFT 9b is connected to the corresponding first TFT 9a and power source line 18g. The first TFT 9b illustrated in FIG. 3 includes: a semiconductor layer 12b; the gate insulating film 13; a gate electrode 14b; the first interlayer insulating film 15; the second interlayer insulating film 17; and a source electrode 18c and a drain electrode 18d all of which are provided on the base coat film 11 in this order. The semiconductor layer 12b illustrated in FIG. 3 is, for example, made of polysilicon film and shaped into an island. The semiconductor layer 12b includes a channel region, a source region, and a drain region. The gate insulating film 13 illustrated in FIG. 3 is provided to cover the semiconductor layer 12b. The gate electrode 14b illustrated in FIG. 3 is provided on the gate insulating film 13 to overlap the channel region of the semiconductor layer 12b. The first interlayer insulating film 15 and the second interlayer insulating film 17 illustrated in FIG. 3 are provided in this order to cover the gate electrode 14b. The source electrode 18c and the drain electrode 18d illustrated in FIG. 3 are spaced apart from each other on the second interlayer insulating film 17. As illustrated in FIG. 3, the source electrode 18c and the drain electrode 18d are respectively connected to the source region and the drain region of the semiconductor layer 12b through contact holes each formed in a multilayer film including the gate insulating film 13, the first interlayer insulating film 15, and the second interlayer insulating film 17.

Note that, as an example, the first TFTs 9a and the second TFTs 9b in this embodiment are top gate TFTs. Alternatively, the first TFTs 9a and the second TFTs 9b may be bottom gate TFTs.

As illustrated in FIG. 4, in each sub pixel P, the capacitor 9c is connected to the corresponding first TFT 9a and power source line 18g. The capacitor 9c illustrated in FIG. 3 includes: a lower conductive layer 14c formed of the same material and in the same layer as the gate electrodes 14a and 14b; the first interlayer insulating film 15 provided to cover the lower conductive layer 14c; and an upper conductive layer 16 provided on the first interlayer insulating film 15 to overlap the lower conductive layer 14c. Note that the upper conductive layer 16 illustrated in FIG. 3 is electrically connected to the power source line 18g through a contact hole formed in the second interlayer insulating film 17.

The planarization film 19a is made of such an organic resin material as polyimide resin.

As illustrated in FIG. 3, the organic EL element 25 includes: a plurality of first electrodes 21a; an edge cover 22a; a plurality of organic EL layers 23; and a second electrode 24 all of which are provided on the planarization film 19a in this order.

The first electrodes 21a illustrated in FIG. 3 are provided on the planarization film 19a in a matrix, so that each of the first electrodes 21a corresponds to one of the sub pixels P. As illustrated in FIG. 3, each of the first electrodes 21a is connected to the drain electrode 18d of a corresponding one of the second TFTs 9b through a contact hole formed in the planarization film 19a. The first electrodes 21a are light-reflective and capable of injecting holes into the organic EL layers 23. Preferably, each of the first electrodes 21a is formed of a material having a high work function in order to improve efficiency in injecting the holes into the organic EL layers 23. Exemplary materials for the first electrodes 21a include such metal materials as silver (Ag), aluminum (Al), vanadium (V), cobalt (Co), nickel (Ni), tungsten (W), gold (Au), titanium (Ti), ruthenium (Ru), manganese (Mn), indium (In), ytterbium (Yb), lithium fluoride (LiF), platinum (Pt), palladium (Pd), molybdenum (Mo), iridium (Ir), and tin (Sn). Moreover, the exemplary materials for the first electrodes 21a may also include an alloy of astatine (At)/astatine dioxide (AtO₂). Furthermore, exemplary materials for the first electrodes 21a may include such conductive oxides as tin oxide (SnO), zinc oxide (ZnO), indium tin oxide (ITO), and indium zinc oxide (IZO). Each of the first electrodes 21a may be a multilayer including two or more layers made of the above materials. Exemplary compound materials having a large work function include indium tin oxide (ITO) and indium zinc oxide (IZO).

The edge cover 22a illustrated in FIG. 3 is provided in a grid to cover an edge of each first electrode 21a. Exemplary materials for the edge cover 22a include such positive photosensitive resins as polyimide resin, acrylic resin, polysiloxane resin, and novolak resin. The edge cover 22a illustrated in FIGS. 3 and 8 has a surface partially provided with the first photo spacers C. In FIG. 3, each of the first photo spacers C is shaped into an island and protrudes upward. That is, between sub pixels P arranged in the display area D, the photo spacers C are provided above the planarization film 19a as illustrated in FIG. 3. Furthermore, between the sub pixels P arranged in the display area D, as illustrated in FIGS. 3 and 8, a plurality of first conductive layers 21c is formed of the same material and in the same layer as the first electrodes 21a. Each of the first conductive layers 21c is shaped into an island and positioned under a corresponding one of the first photo spacers C.

The organic EL layers 23 illustrated in FIG. 3 are each disposed on a corresponding one of the first electrodes 21a, and provided in a matrix to a corresponding one of the sub pixels P. As illustrated in FIG, 5, each of the organic EL layers 23 includes: a hole-injection layer 1; a hole-transport layer 2; a light-emitting layer 3; an electron-transport layer 4; and an electron-injection layer 5 all of which are provided one after another on the first electrode 21a in this order.

The hole injection layer 1, also referred to as an anode buffer layer, is capable of approximating the energy levels of the first electrode 21a and the organic EL layer 23 and increasing efficiency in injection of the holes from the first electrode 21a to the organic EL layer 23. Exemplary materials for the hole injection layer 1 may include triazole derivatives, oxadiazole derivatives, imidazole derivatives, polyarylalkane derivatives, pyrazoline derivatives, phenylenediamine derivatives, oxazole derivatives, styrylanthracene derivatives, fluorenone derivatives, hydrazone derivatives, and stilbene derivatives.

The hole-transport layer 2 is capable of improving efficiency in transporting the holes from the first electrode 21a to the organic EL layer 23. Exemplary materials for the hole transport-layer 2 may include porphyrin derivatives, aromatic tertiary amine compounds, styryl amine derivatives, polyvinyicarbazole, poly-p-phenylene vinylene, polysilane, triazole derivatives, oxadiazole derivatives, imidazole derivatives, polyarylalkane derivatives, pyrazoline derivatives, pyrazolone derivatives, phenylenediamine derivatives, arylamine derivatives, amine-substituted chalcone derivatives, oxazole derivatives, styrylanthracene derivatives, fluorenone derivatives, hydrazone derivatives, stilbene derivatives, hydrogenated amorphous silicon, hydrogenated amorphous silicon carbide, zinc sulfide, and zinc selenide.

The light-emitting layer 3 is a region into which the holes and the electrons are injected from the first electrodes 21a and the second electrode 24 and recombine with each other, when a voltage is applied by the first electrodes 21a and the second electrode 24. This light-emitting layer 3 is formed of a material with high light emission efficiency. Exemplary materials for the light-emitting layer 3 may include metal oxinoid compounds [8-hydroxyquinoline metal complexes], naphthalene derivatives, anthracene derivatives, diphenylethylene derivatives, vinylacetone derivatives, triphenylamine derivatives, butadiene derivatives, coumarin derivatives, benzoxazole derivatives, oxadiazole derivatives, oxazole derivatives, benzimidazole derivatives, thiadiazole derivatives, benzothiazole derivatives, styryl derivatives, styrylamine derivatives, bisstyrylbenzene derivatives, trisstyrylbenzene derivatives, perylene derivatives, perinone derivatives, aminopyrene derivatives, pyridine derivatives, rodamine derivatives, acridine derivatives, phenoxazone, quinacridone derivatives, rubrene, poly-p-phenylene vinylene, and polysilane.

The electron-transport layer 4 is capable of efficiently transporting the electrons to the light-emitting layer 3. Exemplary materials for the electron-transport layer 4 may include, as organic compounds, oxadiazole derivatives, triazole derivatives, benzoquinone derivatives, naphthoquinone derivatives, anthraquinone derivatives, tetracyanoanthraquinodimethane derivatives, diphenoquinone derivatives, fluorenone derivatives, silole derivatives, and metal oxinoid compounds.

The electron-injection layer 5 is capable of approximating the energy levels of the second electrode 24 and the organic EL layer 23, and increasing efficiency in injection of the electrons from the second electrode 24 to the organic EL layer 23. Such a feature makes it possible to decrease a drive voltage of the organic EL element 25. The electron-injection layer 5 may also be referred to as a cathode buffer layer. Exemplary materials for the electron-injection layer 5 may include: such inorganic alkaline compounds as lithium fluoride (LiF), magnesium fluoride magnesium fluoride (MgF₂), calcium fluoride (CaF₂), strontium fluoride (SrF₂), and barium fluoride (BaF₂); aluminum oxide (Al₂O₃); and strontium oxide (SrO).

As illustrated in FIG, 3, the second electrode 24 is provided to cover the organic EL layers 23 and the edge cover 22a. The second electrode 24 is capable of injecting electrons into the organic EL layers 23. Preferably, the second electrode 24 is made of a material having a low work function in order to improve efficiency in injection of the electrons into the organic EL layers 23, Exemplary materials for the second electrode 24 include silver (Ag), aluminum (Al), vanadium (V), cobalt (Co), nickel (Ni), tungsten (W), gold (Au), calcium (Ca), titanium (Ti), yttrium (Y), sodium (Na), ruthenium (Ru), manganese (Mn), indium (In), magnesium (Mg), lithium (Li), ytterbium (Yb), and lithium fluoride (LiF). The second electrode 24 may also be formed of an alloy of magnesium (Mg)/copper (Cu), magnesium (Mg)/silver (Ag), sodium (Na)/potassium (K), astatine (At)/astatine dioxide (AtO₂), lithium (Li)/aluminum (Al), lithium (Li)/calcium (Ca)/aluminum (Al), and lithium fluoride (LiF)/calcium (Ca)/aluminum (Al). The second electrode 24 may also be formed of such conductive oxides as tin oxide (SnO), zinc oxide (ZnO), indium tin oxide (ITO) and indium zinc oxide (IZO). The second electrode 24 may be a multilayer including two or more layers made of the above materials. Exemplary materials having a low work function include magnesium (Mg), lithium (Li), lithium fluoride (LiF), magnesium (Mg)/copper (Cu), magnesium(Mg)/silver (Ag), sodium (Na)/potassium (K), lithium (Li)/aluminum (Al), lithium (Li)/calcium (Ca)/aluminum (Al), and fluoride (LiF)/calcium (Ca)/aluminum (Al).

As illustrated in FIGS. 3 and 6, the sealing film 30 includes: a first inorganic film 26 provided to cover the second electrode 24; an organic film 27 provided on the first inorganic film 26; and a second inorganic film 28 provided to cover the organic film 27. The sealing film 30 is capable of protecting the organic EL layers 23 from such substances as water and oxygen. The first inorganic film 26 and the second inorganic film 28 are made of such inorganic materials as silicon dioxide (SiO₂), aluminum oxide (Al₂O₃), silicon nitride (SiNₓ (where x is a positive integer)) such as trisilicon tetranitride (Si₃N₄), and silicon carbide nitride (SiCN). Exemplary materials for the organic film 27 include such organic materials as acrylic resin, polyuria resin, parylene resin, polyimide resin, and polyamide resin.

As illustrated in FIGS. 6 and 11, the organic EL display device 50a includes, in the frame area F, the frame wire 18h shaped into a substantial C-shape and laid outside the trench G. In the terminal T, the frame wire 18h is electrically connected to a terminal receiving a low power-supply voltage (ELVSS). Moreover, as illustrated in FIG, 6, the frame wire 18h is electrically connected to the second electrode 24 through the second conductive layer 21b. Note that the frame wire 18h is formed of the same material and in the same layer as the source lines 18f.

Furthermore, as illustrated in FIGS. 7 and 11, the organic EL display device 50a includes, in the frame area F, the frame wire 18i shaped into a substantial C-shape and laid behind the trench G. In the terminal T, the frame wire 18i is electrically connected to a terminal receiving a high power-supply voltage (ELVDD). Moreover, near the display area D, the frame wire 18i is electrically connected to the power source lines 18g arranged in the display area D. Note that the frame wire 18i is formed of the same material and in the same layer as the source lines 18f.

Furthermore, as illustrated in FIGS. 3, 6, 9, and 13, the organic EL display device 50a includes, in the frame area F, the second conductive layer 21b shaped into a substantial C-shape and provided to overlap the trench G, and a first dam wall Wa and a second dam wall Wb to be described later. The second conductive layer 21b illustrated in FIG. 6 is provided on three of the sides, of the frame area F, not along the terminal T; that is, on the two sides not facing the terminal T and one of the two sides which face the terminal T. Here, the one side extends away from the terminal T. The second conductive layer 21b covers top surfaces and side surfaces of planarization films 19b and 19c included in the first dam wall Wa and the second dam wall Wb. Moreover, as illustrated in FIGS. 3 and 6, the second conductive layer 21b is electrically connected to the second electrode 24 through the trench G. The second conductive layer 21b illustrated in FIG. 6 is electrically connected to the frame wire 18h. Furthermore, the second conductive layer 21b includes a plurality of openings M each formed under a corresponding one of the second photo spacers 22b and 22c to be described later. Note that the second conductive layer 21b is formed of the same material and in the same layer as the first electrodes 21a.

Moreover, as illustrated in FIGS. 7, 10, and 13, the organic EL display device 50a includes the third conductive layer 21d shaped into a strip. The third conductive layer 21d is provided to overlap the first dam wall Wa and the second dam wall Wb on one side, of the frame area F, along the terminal T. Here, the one side is one of two sides facing the terminal T, and is positioned closer to the terminal T. The third conductive layer 21d illustrated in FIG. 7 is provided on the one side, of the frame area F, along the terminal T. The third conductive layer 21d covers top surfaces and side surfaces of the planarization films 19b and 19c included in the first dam wall Wa and the second dam wall Wb. The third conductive layer 21d illustrated in 7 is electrically connected to the frame wire 18i. Note that the third conductive layer 21d is formed of the same material and in the same layer as the first electrodes 21a. As can be seen, the third conductive layer 21d functions as a trunk wire for a high power-source voltage, making it possible to reduce electric resistance of wires, including the frame wire 18i, receiving the high power-source voltage.

Furthermore, as illustrated in FIGS. 3, 6 and 7, the organic EL display device 50a includes, on the planarization film 19a in the frame area F, the second photo spacers 22b and 22c each shaped into an island and protruding upward in the drawing. The second photo spacers 22b illustrated in FIGS. 3, 6, and 9 are provided in the area Ab (see FIG. 12) outside the trench G (on the right in the drawings). The second photo spacers 22c illustrated in FIGS. 3, 6, and 9 are provided in the area Aa (see FIG. 12) behind the trench G (on the left in the drawings). The second photo spacers 22b and 22c have a height Hb from a top surface of the planarization film 19a. As illustrated in FIG. 3, the height Hb is greater than a height Ha, of the first photo spacers C, from the top surface of the planarization film 19a. Note that the second photo spacers 22b and 22c are formed of the same material and in the same layer as the edge cover 22a.

Moreover, in the organic EL display device 50a as illustrated in FIGS. 1, 6, 7, 9, and 10, the frame area F is provided with the first dam wall Wa and the second dam Wb. The first dam wall Wa is provided around the second photo spacers 22b and shaped into a frame to overlap an edge of the organic film 27 of the sealing film 30. The second dam wall Wb is shaped into a frame and provided around the first dam wall Wa.

The first dam wall Wa illustrated in FIG. 6 is formed on the three sides, of the frame area F, not along the terminal T. The first dam wall Wa includes: the planarization film 19b formed in the same layer and of the same material as the planarization film 19a; the second conductive layer 21b; and a resin layer 22d, all of which are stacked in this order. The resin layer 22d is formed in the same layer and of the same material as the edge cover 22a. The first dam wall Wa illustrated in FIG. 7 is formed on the one side, of the frame area F, along the terminal T. The first dam wall Wa includes: the planarization film 19b formed in the same layer and of the same material as the planarization film 19a; the third conductive layer 21d; and the resin layer 22d, all of which are stacked in this order. The resin layer 22d is formed in the same layer and of the same material as the edge cover 22a.

The second dam wall Wb illustrated in FIG. 6 is formed on the three sides, of the frame area F, not along the terminal T. The second dam wall Wb includes: the planarization film 19c formed in the same layer and of the same material as the planarization film 19a; the second conductive layer 21b; and a resin layer 22e, all of which are stacked in this order. The resin layer 22e is formed in the same layer and of the same material as the edge cover 22a. The second dam wall Wb illustrated in FIG. 7 is formed on the one side, of the frame area F, along the terminal T. The second dam wall Wb includes: the planarization film 19c formed in the same layer and of the same material as the planarization film 19a; the third conductive layer 21d; and the resin layer 22e, all of which are stacked in this order. The resin layer 22e is formed in the same layer and of the same material as the edge cover 22a. Of the three sides, of the frame area F, not along the terminal T, the resin layer 22d has a height Hc from the top surface of the planarization film 19a. As illustrated in FIG. 6, the height Hc is as great as a height Hd, of the resin layer 22e, from the top surface of the planarization film 19a, and is smaller than the height Hb, of the second photo spacers 22h and 22c, from the top surface of the planarization film 19a. In the same manner, on the one side, of the frame area F, along the terminal T, the resin layer 22d has the height Hc from the top surface of the planarization film 19a. As illustrated in FIG. 7, the height Hc is as great as the height Hd, of the resin layer 22e, from the top surface of the planarization film 19a, and is smaller than the height Hb, of the second photo spacers 22b and 22c, from the top surface of the planarization film 19a.

The above organic EL display device 50a displays an image as follows: In each sub pixel P, a gate signal is input through the gate line 14 to the first TFT 9a. The first TFT 9a turns ON. Through the source line 18f, a predetermined voltage corresponding to a source signal is written in the gate electrode 14b of the second TFT 9b and the capacitor 9c. In accordance with the gate voltage of the second TFT 9b, a current is defined in accordance with a gate voltage of the second TFT 9b and supplied from the power source line 18g to the organic EL layer 23. The supplied current allows the light-emitting layer 3 of the organic EL layer 23 to emit light and display the image. Note that, in the organic EL display device 50a, even if the first TFT 9a turns OFF, the gate voltage of the second TFT 9b is held in the capacitor 9c. Hence, the fight-emitting layer 3 keeps emitting light until a gate signal of the next frame is input.

Described next is a method for manufacturing the organic EL display device 50a of this embodiment. Note that the method for manufacturing the organic EL display device 50a of this embodiment includes: forming TFT layer; forming organic EL element; and forming sealing film.

### Forming TFT Layer

On a surface of the resin substrate layer 10 formed on a glass substrate, for example, t base coat film 11, the first TFTs 9a, the second TTFs 9b, the capacitors 9c, and the planarization film 19a are formed with a known technique to form the TFT layer 20a.

### Forming Organic EL Element

On the planarization film 19a of the TFT layer 20a formed in the forming TFT layer, the first electrodes 21a, the edge cover 22a, the organic EL layers 23 (each including the hole-injection layer 1, the hole-transport layer 2, the light-emitting layer 3, the electron-transport layer 4, and the electron-injection layer 5), and the second electrode 24 are formed with a known technique to form the organic EL element 25. In forming the first electrodes 21a, the first, second, and third conductive layers 21c, 21b, and 21d are simultaneously formed. In forming the edge cover 22a, the first photo spacers C, the second photo spacers 22b and 22c, and the resin layers 22d and 22e are simultaneously formed. Here, the first conductive layers 21c, which reflect light, are positioned under the first photo spacers C. This is why the positive photosensitive resin is exposed from a rear surface thereof, so that the first photo spacers C are formed relatively low (see the height Ha in FIG. 3). The second conductive layer 21b, which reflects light, is not positioned under the second photo spacers 22b and 22c (i.e., the openings M are positioned under the second photo spacers 22b and 22c). This is why the positive photosensitive resin is not exposed from a rear surface thereof, so that the second photo spacers 22b and 22c are formed relatively high (see the height Hb>the height Ha in FIG. 3). Here, the second and third conductive layers 21b and 21d, which reflect light, are positioned under the resin layers 22d and 22e. This is why the positive photosensitive resin is exposed from a rear surface thereof, so that the resin layers 22d and 22e are formed relatively low (see the heights Hc and Hd<the height Hb in FIG. 6).

Here, the first photo spacers C come into contact with: a fine metal mask (FMM) which allows patterning for each of the sub pixels; and a common metal mask (CMM), which allows patterning for each of the panels, to be used for forming functional layers other than the second electrode 24. However, the first photo spacers C do not come into contact with a CMM to be used for forming the second electrode 24. Moreover, the second photo spacers 22b come into contact with the CMM to be used for forming the second electrode 24. Thus, in vapor-deposition using the FMM, for example, the height Ha is smaller than the height Hb so that the second photo spacers 22b and 22c first come into contact with the FMM, making it possible to reduce an impact caused when the first photo spacers C come into contact with the FMM. Such a feature keeps the first photo spacers C from breaking, making it possible to reduce the risk that the broken pieces of the first photo spacers C act as foreign objects. Moreover, in vapor-deposition using the CMM, as well as in vapor-deposition using the FMM, the heights He and Hd are smaller than the height Hb. This is why neither the first dam wall Wa nor the second dam wall Wb comes into contact with the CMM. Even if the first dam wall Wa and the second dam wall Wb come into contact with the CMM, the impact in the contact is small. Such features make it possible to reduce damage to the first dam wall Wa and the second dam wall Wb.

Moreover, in vapor-depositing the functional layers other than the second electrode 24 using the CMM, the CMM comes into contact with the second photo spacers 22b and 22c for the vapor-depositing. In vapor-depositing the second electrode 24, the CMM comes into contact with the second photo spacers 22b for the vapor-depositing. That is, an opening of the CMM to be used for forming the functional layers other than the second electrode 24 is smaller than that of the CMM to be used for forming the second electrode 24. Thanks to such a feature, an unnecessary functional layer is less likely to be vapor-deposited between the second electrode 24 and the second conductive layer 21b, allowing the second electrode 24 and the second conductive layer 21b to directly come into contact with each other and reducing electric resistance.

### Forming Sealing Film

First, on a surface of a substrate including the organic EL element 25 formed in the above forming organic EL element, an inorganic insulating film such as a silicon nitride film, a silicon oxide film, or a silicon nitride oxide film is deposited by, for example, the plasma chemical vapor deposition (CVD) using the CMM to form the first inorganic film 26.

Next, on a surface of the substrate including the first inorganic film 26, an organic resin material such as acrylic resin is applied by, for example, an inkjet technique to form the organic film 27.

Moreover, on a substrate including the organic film 27, an inorganic insulating film such as a silicon nitride film, a silicon oxide film, or a silicon nitride oxide film is deposited as the second inorganic film 28 by the plasma CVD using the CMM. Hence, the sealing film 30 is formed.

Finally, on a surface of a substrate including the sealing film 30, a not-shown protective sheet is attached. After that, a laser beam is emitted on the glass substrate of the resin substrate layer 10 to remove the glass substrate from the bottom surface of the resin substrate layer 10. Furthermore, on the bottom surface of the resin substrate layer 10 with the glass substrate removed, a not-shown protective sheet is attached.

Through the above steps, the organic EL display device 50a of this embodiment can be manufactured.

As can be seen, in the organic EL display device 50a of this embodiment, the first photo spacers C are provided above the planarization film 19a in the display area D. The first conductive layers 21c, formed of the same material and in the same layer as the first electrodes 21a, are each formed under a corresponding one of the first photo spacers C. In the frame area F, the second photo spacers 22b and 22c are provided on the planarization film 19a. The second conductive layer 21b, formed of the same material and in the same layer as the first electrodes 21a, includes the openings M each formed under a corresponding one of the second photo spacers 22b and 22c. In forming the edge cover 22a, its positive photosensitive resin has a portion on which the first photo spacers C are formed. Because the portion is also exposed from its rear surface, the height Ha of the first photo spacers C is relatively small. The positive photosensitive resin has a portion on which the second photo spacers 22b and 22c are formed. Because the portion is not exposed from its rear surface, the height Hb of the second photo spacers 22b and 22c is relatively greater than the height Ha. Such features make it possible to control light exposure of the photosensitive resin for each position on the substrate without using a multi-tone mask. Hence, the difference can be readily made between the height Ha of each of the first photo spacers C arranged in the display area D and the height Hb of each of the second photo spacers 22b and 22c arranged in the frame area F. Furthermore, the height Ha of each of the first photo spacers C arranged in the display area D is smaller than the height Hb of each of the second photo spacers 22b and 22c arranged in the frame area F. Such a feature makes it possible to reduce damage to the first photo spacers C caused when a vapor-deposition mask comes into contact with the first photo spacers C.

Moreover, in the organic EL display device 50a of this embodiment, the first dam wall Wa and the second dam wall Wb are lower than the second photo spacers 22b and 22c. This is why the vapor-deposition mask does not come into contact with the first dam wall Wa or the second dam wall Wb. Even if the vapor-deposition mask comes into contact with the first dam wall Wa or the second dam wall Wb, the damage to the dam walls is reduced. Such features make it possible to reliably provide the sealing film 30 with sealing capability.

### Second Embodiment

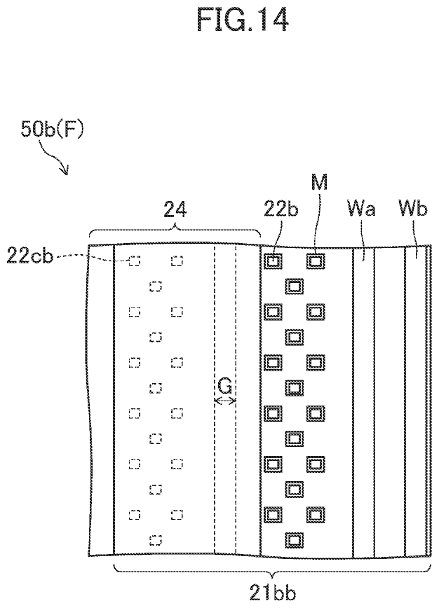

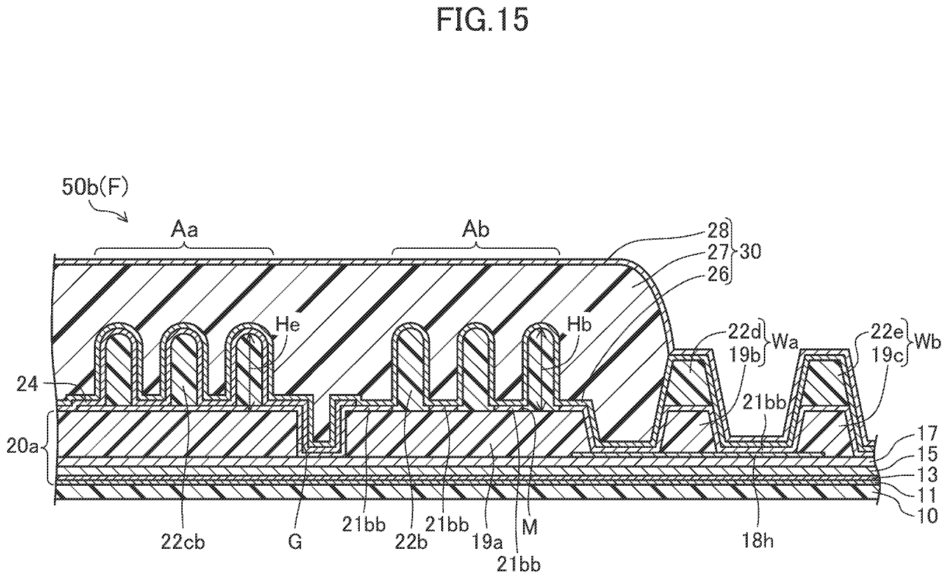

FIGS. 14 and 15 illustrate a second embodiment of a display device according to the present invention. FIG. 14 is a plan view illustrating how the second photo spacers 22b and third photo spacers 22cb are arranged on a side, of the frame area F, not facing the terminal T of an organic EL display device 50b according to the second embodiment. FIG. 15 is a cross-section corresponding to FIG. 6, and illustrating the frame area F of the organic EL display device 50b. Note that, in the embodiment below, like reference signs designate identical or corresponding components in FIGS. 1 to 13. These components will not be elaborated upon.

The above first embodiment describes as an example the organic EL display device 50a including the second photo spacers 22b and 22c having the same height and arranged to face each other across the trench G. This embodiment describes as an example the organic EL display device 50b including the second photo spacers 22b and the third photo spacers 22cb having different heights and arranged to face each other across the trench G.

Similar to the organic EL display device 50a of the first embodiment, the organic EL display device 50b includes: the display area D; and the frame area F provided around the display area D.

As illustrated in FIG. 15, the organic EL display device 50b includes: the resin substrate layer 10; the TFT layer 20a provided on the resin substrate layer 10; the organic EL element 25 (see FIG. 3) provided on the TFT layer 20a; and the sealing film 30 provided to cover the organic EL element 25.

Moreover, as illustrated in FIG. 15, the organic EL display device 50b includes, in the frame area F, the frame wire 18h shaped into a substantial C-shape and laid outside the trench G.

Similar to the organic EL display device 50a of the first embodiment, the organic EL display device 50b also includes, in the frame area F, the frame wire 18i is shaped into a substantial C-shape and laid behind the trench G.

Furthermore, as illustrated in FIGS. 14 and 15, the organic EL display device 50b includes, in the frame area F, a second conductive layer 21bb shaped into a substantial C-shape and provided to overlap the trench G, the first dam wall Wa, and the second dam wall Wb. The second conductive layer 21bb illustrated in 15 is provided on three of the sides, of the frame area T, not along the terminal T. The second conductive layer 21bb covers top surfaces and side surfaces of the planarization films 19b and 19c included in the first dam wall Wa and the second dam wall Wb. The second conductive layer 21bb illustrated in FIG. 15 is electrically connected to the second electrode 24 through the trench G. Moreover, the second conductive layer 21bb illustrated in FIG. 15 is electrically connected to the frame wire 18h. Furthermore, the second conductive layer 21bb includes the openings M each formed under a corresponding one of the second photo spacers 22b. Note that the second conductive layer 21bb is formed of the same material and in the same layer as the first electrodes 21a. As illustrated in FIG. 15, the second conductive layer 21bb comes into contact with the second electrode 24 in the frame area F, and is electrically connected to the second electrode 24.

Similar to the organic EL display device 50a of the above first embodiment, the organic EL display device 50b includes the third conductive layer 21d shaped into a strip. The third conductive layer 21d is provided to overlap the first dam wall Wa and the second dam wall Wb on the one side, of the frame area F, along the terminal T. The third conductive layer 21d is electrically connected to the power source lines 18g, of the display area D, receiving a high power-source voltage (ELVDD). Note that, if the light-emitting element is of an inverted type with a cathode, a light-emitting layer, and an anode arranged in this order from the substrate, the power source lines 18g in the display area D receives a low power-source voltage (ELDSS).

Furthermore, as illustrated in FIGS. 14 and 15, the organic EL display device 50b includes, on the planarization film 19a in the frame area F, the second photo spacers 22b and third spacers 22cb each shaped into an island and protruding upward in the drawings. The second photo spacers 22b illustrated in FIGS. 14 and 15 are provided in the area Ab outside the trench G (on the right in the drawings). The third photo spacers 22cb illustrated in FIGS. 14 and 15 are provided in the area Aa behind the trench G (on the left in the drawings) to overlap the second conductive layer 21bb. The second photo spacers 22b have the height Hb from the top surface of the planarization film 19a. The height Hb is greater than the height Ha, of the first photo spacers C, from the top surface of the planarization film 19a. The third photo spacers 22cb have a height He from the top surface of the planarization film 19a. The height He is smaller than the height Hb, of the second photo spacers 22b, from the top surface of the planarization film 19a. Note that the third photo spacers 22cb are formed of the same material and in the same layer as the edge cover 22a.

Moreover, as illustrated in FIG. 15, the organic EL display device 50b includes in the frame area F the first dam wall Wa and the second dam Wb. The first dam wall Wa is provided around the second photo spacers 22b, and shaped into a frame to overlap an edge of the organic film 27 of the sealing film 30. The second dam wall Wb is shaped into a frame and provided around the first dam wall Wa.

Similar to the organic EL display device 50a of the above first embodiment, the organic EL display device 50b is flexible, and allows, in each of the sub pixels P, the light-emitting layer 3 of the organic EL layer 23 to appropriately emit light through the first TFTs 9a and the second TFTs 9b to display an image.

The organic EL display device 50b of this embodiment can be manufactured by the method for manufacturing the organic EL display device 50a of the above first embodiment. In the method, the second conductive layer 21b is patterned into a different shape. When the edge cover 22a is formed, the portion of the positive photosensitive resin on which the third photo spacers 22cb are formed is exposed also from a rear surface of the portion so that the third photo spacers 22cb are formed.

As can be seen, in the organic EL display device Sob of this embodiment, the first photo spacers C are provided above the planarization film 19a in the display area D. The first conductive layers 21c, formed of the same material and in the same layer as the first electrodes 21a, are each formed under a corresponding one of the first photo spacers C. In the frame area F, the second photo spacers 22b are provided on the planarization film 19a. The second conductive layer 21bb, formed of the same material and in the same layer as the first electrodes 21a, includes the openings M each formed under a corresponding one of the second photo spacers 22b. In forming the edge cover 22a, its positive photosensitive resin has a portion on which the first photo spacers C are formed. Because the portion is also exposed from its rear surface, the height Ha of the first photo spacers C is relatively small. The positive photosensitive resin has a portion on which the second photo spacers 22b are formed. Because the portion is not exposed from its rear surface, the height Hb of the second photo spacers 22b is relatively greater than the height Ha. Such features make it possible to control light exposure of the photosensitive resin for each position on the substrate without using a multi-tone mask. Hence, the difference can be readily made between the height Ha of each of the first photo spacers C arranged in the display area D and the height Hb of each of the second photo spacers 22b arranged in the frame area F. Furthermore, the height Ha of the first photo spacers C arranged in the display area D is smaller than the height Hb of the second photo spacers 22b arranged in the display area F. Such a feature makes it possible to reduce damage to the first photo spacers C caused when a vapor-deposition mask comes into contact with the first photo spacers C.

Moreover, in the organic EL display device 50b of this embodiment, the first dam wall Wa and the second dam wall Wb are lower than the second photo spacers 22b. This is why the vapor-deposition mask does not come into contact with the first dam wall Wa or the second dam wall Wb. Even if the vapor-deposition mask comes into contact with the first dam wall Wa or the second dam wall Wb, the damage to the dam walls is reduced. Such features make it possible to ensure sealing capability of the sealing film 30.

Furthermore, in the organic EL display device 50b of this embodiment, the height Hb of the second photo spacers 22b is greater than the height He of the third photo spacers 22cb. Hence, the second photo spacers 22b away from the display area D come into contact with a vapor-deposition mask before the third photo spacers 22cb closer to the display area D. Such a feature reduces an impact when the vapor-deposition masks comes into contact with the third photo spacers 22cb, making it possible to keep from generating particles and reduce the risk that the particles come toward the display area D.

### Other Embodiments

In the above embodiments, each organic EL layer is formed of a multilayer including such five layers as the hole-injection layer, the hole-transport layer, the light-emitting layer, the electron-transport layer, and the electron-injection layer. Alternatively, the organic EL layer may be formed of a multilayer including such three layers as a hole-injection and hole-transport layer, the light-emitting layer, and an electron-transport and electron-injection layer.

Moreover, in the organic EL display devices of the above embodiments described as examples, the first electrodes are anodes and the second electrode is a cathode. Alternatively, the present invention is applicable to an organic EL display device whose multilayered structure is inverted so that the first electrodes are cathodes and the second electrode is an anode.

Furthermore, in the organic EL display devices of the above embodiments described as examples, the electrodes of the TFTs connected to the first electrodes are drain electrodes. Alternatively, the present invention is applicable to an organic EL display device in which the electrodes of the TFTs connected to the first electrodes are referred to as source electrodes.

In addition, the display devices of the embodiments described as examples are organic EL display devices. Alternatively, the present invention is applicable to a display device including a plurality of light-emitting elements driven by a current. For example, the present invention is applicable to a display device including quantum-dot light emitting diodes (QLEDs); that is light-emitting elements using layers containing quantum dots.

### INDUSTRIAL APPLICABILITY

As can be seen, the present invention is applicable to a flexible display device.

### REFERENCE SIGNS LIST

C First Photo Spacers
D Display Area
F Frame Area
G Trench
M Opening
T Terminal
Wa First Dam Wall
Wb Second Dam Wall
10 Resin Substrate Layer (Base Substrate)
18g Power Source Line
19a˜19c Planarization Film
20a TFT
21a First Electrode
21b Second Conductive Layer
21c First Conductive Layer
21d Third Conductive Layer
22a Edge Cover
22b, 22c Second Photo Spacer
22cb Third Photo Spacer
22d, 72e Resin Layer
24 Second Electrode
25 Organic EL Element (Light-Emitting Element)
50a, 50b Organic EL Display Device

1. A display device, comprising:
a base substrate on which a display area for displaying an image and a frame area around the display area are defined;
a TFT layer provided on the base substrate and including a planarization film configuring a top surface of the TFT layer;
a light-emitting element provided on the planarization film in the display area, the light-emitting element including a plurality of first electrodes, a light-emitting layer, and a second electrode stacked in this order;
a plurality of first photo spacers provided above the planarization film in the display area; and
a plurality of second photo spacers provided on the planarization film in the frame area,
the display area being provided with a plurality of first conductive layers formed of the same material and in the same layer as the first electrodes, the first conductive layers being each shaped into an island and positioned under a corresponding one of the first photo spacers,
the frame area being provided with a second conductive layer formed of the same material and in the same layer as the first electrodes, and
the second conductive layer including a plurality of openings each formed under a corresponding one of the second photo spacers.

2. The display device according to claim 1, wherein
the first photo spacers have a height, from a top surface of the planarization film, smaller than a height, of the second photo spacers, from the top surface of the planarization film.

3. The display device according to claim 2, wherein
the first photo spacers and the second photo spacers are formed of positive photosensitive resin.

4. The display device according to claim 1, wherein
the first electrodes reflect light.

5. The display device according to claim 1, wherein
the frame area is provided with a first dam wall and a second dam wall in this order, the first dam wall and the second dam wall being shaped into a frame and provided around the second photo spacers, and
the first dam wall and the second dam wall include: the planarization film, the second conductive layer, and a resin layer stacked in this order, the resin layer being formed of the same material and in the same layer as the second photo spacers.

6. The display device according to claim 5, wherein
the display area is shaped into a rectangle,
the frame area has an end provided with a terminal,
the second conductive layer is provided on a side, of the frame area, not facing the terminal, the second conductive layer covering a top surface and a side surface of the planarization film included in the first dam wall and the second dam wall, and
the resin layer has a height, from a top surface of the planarization film, smaller than a height, of the second photo spacers, from the top surface of the planarization film.

7. The display device according to claim 6, wherein
the second conductive layer is electrically connected to the second electrode.

8. The display device according to claim 5, wherein
the display area is shaped into a rectangle,
the frame area has an end provided with a terminal,
on one of two sides facing the terminal of the frame area, a third conductive layer is formed of the same material and in the same layer as the first electrodes, the one side being positioned closer to the terminal,
the third conductive layer is provided to cover a top surface and a side surface of the planarization film included in the first dam wall and the second dam wall,
the first dam wall and the second dam wall are formed of the planarization film, the third conductive layer, and the resin layer stacked, and
the resin layer has a height, from a top surface of the planarization film, smaller than a height, of the second photo spacers, from the top surface of the planarization film.

9. The display device according to claim 8, wherein
the third conductive layer is electrically connected to a power source line receiving a high power-source voltage.

10. The display device according to claim 1, wherein
in the frame area, the planarization film is provided with a trench penetrating the planarization film and laid around the display area,
the second photo spacers are provided outside the trench,
in the frame area, a plurality of third photo spaces are provided on the planarization film behind the trench, and
the third photo spacers are provided to overlap the second conductive layer.

11. The display device according to claim 10, wherein
the third photo spacers have a height, from a top surface of the planarization film, smaller than a height, of the second photo spacers, from the top surface of the planarization film.

12. The display device according to claim 1, wherein
the light-emitting element includes an edge cover provided to cover an edge of the first electrodes, and
each of the first photo spacers is a protruding portion of a top surface of the edge cover.

13. The display device according to claim 1, wherein
the light-emitting element is an organic electroluminescence (EL) element.
